(19) United States
(12) Patent Application Publication
(10) Pub. No.: US 2007/0063240 A1
(43) Pub. Date: Mar. 22, 2007

(54) Integrated electronic circuit incorporating a capacitor

(75) Inventors: Joaquin Torres, St. Martin Le Vinoux (FR); Alexis Farcy, La Ravoire (FR)

Correspondence Address: JENKENS & GILCHRIST, PC, 1445 ROSS AVENUE, SUITE 3200, DALLAS, TX, 75202, US

(73) Assignee: STMicroelectronics (Crolles 2) SAS, Crolles (FR)

(21) Appl. No.: 11/518,539

(22) Filed: Sep. 7, 2006

(30) Foreign Application Priority Data
Sep. 12, 2005 (FR) 0509286

(51) Int. Cl. H01L 29/94

(52) U.S. Cl. 257/296

(57) ABSTRACT

An integrated electronic circuit includes electrical connections located in metallization layers superposed on top of a substrate. The circuit further incorporates a capacitor having two plates that are placed in two adjacent metallization layers. Each of the metallization layers containing a capacitor plate further contains electrical connections. The capacitor is compatible with a high level of integration of the circuit and may be produced using the damascene process.

### PRIORITY CLAIM

The present application claims priority from French Patent Application No. 05 09286 filed Sep. 12, 2005, the disclosure of which is hereby incorporated by reference.

### BACKGROUND OF THE INVENTION

1. Technical Field of the Invention

The present invention relates to an integrated electronic circuit that incorporates a capacitor, and also to a process for producing such a circuit.

2. Description of Related Art

Many integrated electronic circuits incorporating one or more capacitors already exist. Mention may be made in particular of SRAM (Static Random Access Memory) circuits in which two capacitors are generally associated with each memory cell for storing a bit. When the storage capacity of such a circuit is high, a large number of capacitors have to be incorporated into the circuit.

Usually, an integrated electronic circuit comprises a substrate with transistors produced on its surface, and metallization layers that are superposed on top of the surface of the substrate. The capacitors that are incorporated into such a circuit are placed within specific metallization layers that are inserted between metallization layers dedicated to the formation of electrical connections. These connections connect together various electronic components of the circuit, and also external connection terminals of the integrated circuit that are intended, for example, for supplying the circuit with electrical power or for its inputs/outputs. However, the volume within the circuit that is occupied by an integrated capacitor may be relatively large, especially compared with the portion of the area of the substrate that is occupied by each transistor in the case of recent technologies for producing MOS (Metal-Oxide-Semiconductor) transistors.

Now the storage capacity of SRAM circuits required for certain applications is continuing to increase, as is the level of integration of the transistors. It is therefore necessary to produce integrated capacitors in electronic circuits that do not limit, or only slightly limit, the level of integration of these circuits.

There is a need for a configuration of an integrated electronic circuit incorporating a capacitor which is compatible with a high level of integration of the circuit and, possibly, with the integration of a large number of capacitors into the circuit.

### SUMMARY OF THE INVENTION

To this end, an embodiment proposes an integrated electronic circuit comprising a substrate and electrical connections located in metallization layers superposed on top of a surface of said substrate. The circuit incorporates at least one capacitor having two electrodes that are superposed on and parallel to the surface of the substrate. The two electrodes of the capacitor are placed in adjacent metallization layers, each furthermore containing electrical connections.

Thus, a metallization layer containing an electrode of the capacitor also contains electrical connections. These electrical connections are placed in the metallization layer at a certain distance from the electrode, so that the metallization layer can be used over its entire extent parallel to the surface of the substrate.

Furthermore, by placing electrical connections in the same metallization layers as those containing the electrodes of the capacitor, it is possible for each electrode to be easily connected to other components of the circuit. This results in additional optimization of the circuit during its design, and also a higher level of integration for the circuit. The footprint of the circuit, parallel to the surface of the substrate, which results from the capacitor and the connections which electrically connect it is small. In particular, a track can directly connect an electrode within any one layer. One of the two electrodes of the capacitor may also possess an extension that extends from one side of the other electrode, parallel to the surface of the substrate. A via produced in an adjacent level and terminating on the extension can therefore form a very simple way of electrically connecting the electrode.

The capacitor is compatible with the damascene and dual-damascene processes, which are well mastered at the present time, so that high efficiencies are obtained for producing circuits with capacitors. Thus, the metallization layers are advantageously damascene or dual-damascene layers. The two electrodes are then based on copper and are located in the respective cavities of the corresponding metallization layers.

Advantageously, the electrode closest to the substrate may be located in a damascene layer, that is to say in a metallization layer having only a single level, of tracks and/or of vias. This electrode may therefore be electrically connected by tracks etched in the same layer at the same time as the electrode. The manufacturing cost of the circuit is therefore reduced.

The electrode furthest from the substrate is preferably located in a via level of a dual-damascene layer, that is to say a metallization layer having this level of vias and also a level of tracks lying just above the level of vias, these tracks and these vias being etched in a single step and then simultaneously filled with one or more conducting materials. The manufacturing cost of the circuit can thus be further reduced.

According to a preferred embodiment, the capacitor comprises, in the order starting from that side of the capacitor which is closest to the substrate: a first electrode, optionally a first layer forming an atom diffusion barrier, a dielectric layer, a layer forming an atom diffusion barrier and a second electrode. The circuit is therefore not impaired by atoms coming from the electrodes, which could diffuse out of them when the circuit is heated during its production or its use. Preferably, the first and second barrier layers are made of identical materials. The two electrodes then have identical interfacial, especially electronic, properties with respect to the layer of dielectric. This results in symmetry of electrical operation of the capacitor when the bias of the capacitor is reversed. Advantageously, the material(s) of the (each) barrier layer is (are) electrically conducting so as to obtain a higher capacitance of the capacitor. This is because the thickness of the electrically insulating space lying between the electrodes is then limited to the thickness of only the layer of dielectric. However, for certain capacitor configurations, the first and second barrier layers may be electrically insulating and electrically conducting, respectively.

The integrated electronic circuit may comprise a stack of 2n superposed electrodes parallel to the surface of the substrate, counted starting from the electrode closest to the substrate, n being an integer strictly greater than 1, the electrodes 2i and 2i−1 forming together a capacitor as described above for each integer i from 1 to n. Such circuit has the following electrical connections:

the electrodes 2j and 2j+1 are electrically connected together, for each strictly positive integer j less than n;

the electrodes 1 and 4k+1 are electrically connected together to form a first input of a capacitive system comprising the 2n electrodes, for any strictly positive integer k less than or equal to n/2; and

the electrodes 3 and 4l+3 are electrically connected together to form a second input of the capacitive system, for any strictly positive integer 1 less than n/2.

In such a circuit, the capacitors formed by the electrodes 2i and 2i−1 are connected in series and/or in parallel. The stack of electrodes obtained is compact and compatible with a high level of integration of the circuit. It constitutes a capacitive system whose capacitance may be easily varied by increasing the number n. Advantageously, the electrodes 2j and 2j+1 are placed in adjacent metallization layers and are in electrical contact with each other over a contact area substantially equal to the area of the electrode 2j parallel to the surface of the substrate. Thus, the electrodes 2j and 2j+1 are electrically connected together without requiring additional connections. The capacitive system is then simplified and even more compact, especially along the direction of the stack.

Optionally, the electrodes 2i and 2i′ are identical, i and i′ being two strictly positive integers less than or equal to n. In this case, the shape and the dimensions of the electrodes 2i and 2i′ may be defined by one and the same lithography mask. All the electrodes 2i may be identical and produced using a single lithography mask, which is used again during the production of each of them. As a result, the additional cost of the circuit caused by incorporating the capacitive system into the metallization layers is minimal.

Finally, an embodiment proposes a process for producing an electronic circuit that incorporates a capacitor. Such a process comprises:

/a/ forming a first layer (101) of electrically insulating material on top of and parallel to a surface (S) of a substrate of the circuit;

/b/ etching, respectively in the first layer (101) of insulating material, first cavities (C11, C1), corresponding to first electrical connections (15) and to at least a first electrode of the capacitor (1);

/c/ filling the first cavities (C11, C1) with a first electrically conducting material (100) so as to form the first connections (15) and the first electrode (1);

/d/ removing the first conducting material (100) between the first connections (15) and around the first electrode (1) above the first layer (101) of insulating material;

/e/ forming a second layer (102) of electrically insulating material on the first layer (101);

/f/ etching, in the second layer (102) of insulating material, at least a second cavity (C2) corresponding to a second electrode of the capacitor (2), lying above the first electrode (1);

/g/ forming a layer (21) of a dielectric covering the bottom and the walls of the second cavity corresponding to the second electrode (C2);

/h/ etching second cavities (C23, C25) corresponding to second electrical connections (23, 25) in the second layer (102) of insulating material;

/i/ filling the second cavities (C23, C25, C2) with at least a second electrically conducting material (200, 300) so as to form the second connections (23, 25) and the second electrode (2); and

/j/ removing the second conducting material (200, 300) between the second connections (23, 25) and/or around the second electrode (2) above the second layer (102) of insulating material.

Certain of these steps may be carried out in accordance with the damascene or dual-damascene processes. They are therefore well mastered by those skilled in the art, so that a high fabrication yield may be obtained. Furthermore, the production tools and the chemicals needed are commercially available.

The process may advantageously include at least some of the following improvements, each of which may be implemented separately or in combination with other improvements:

steps /d/ and/or /j/ may each comprise at least one chemical-mechanical polishing operation;

the second cavity corresponding to the second electrode of the capacitor, etched in step /f/, may extend through the second layer of insulating material between two opposed sides of the latter, in a direction perpendicular to the surface of the substrate;

the first cavity corresponding to the first electrode of the capacitor may possess an extension that extends beyond one edge of the second electrode of the capacitor parallel to the surface of the substrate, and one of the second cavities corresponding to a second connection may be etched in step /h/ in the second layer of insulating material in order to form an electrical connection that connects said first electrode to the extension; and

certain of the first electrical connections formed at the same time as the first electrode of the capacitor in step /c/ may comprise tracks.

The process may further include the following steps:

between steps /f/and /g/, producing a first layer of a material forming an atom diffusion barrier is formed, said layer covering the bottom and walls of the second cavity corresponding to the second electrode; and

between steps /g/, and /i/, producing a second layer of a material forming an atom diffusion barrier, said layer covering the bottom and the walls of the second cavity that corresponds to the second electrode and that is already provided with the layer of dielectric.

The respective materials of the first and second barrier layers may be identical, both being electrically conducting, or may be electrically insulating and electrically conducting respectively.

The process may further include the following steps:

/k/ forming a third layer (103) of electrically insulating material on the second layer (102) of insulating material;

/l/ etching, in the third layer (103) of insulating material, third cavities corresponding to third electrical connections (33, 35) and to at least one contact electrode (3) for electrically contacting the second electrode of the capacitor (2) respectively, the third cavity that corresponds to the contact electrode being located above the second electrode (2) and extending through the third layer (103) of insulating material between two opposed sides of said third layer, along the direction perpendicular to the surface of the substrate (N); and

/m/ filling the third cavities with a third electrically conducting material (300) so as to form the third connections (33, 35) and the contact electrode (3) for contacting the second electrode.

Optionally, step /h/ may be carried out at the same time as step /l/, after step /k/. Step /i/ is therefore carried out at the same time as step /m/. The second and third connections may therefore be vias and tracks of a dual-damascene metallization layer, respectively.

One of the third cavities corresponding to a third connection may be etched at step /l/ through the third layer of insulating material in order to form an electrical connection that extends that connection which connects the first electrode of the capacitor through the second layer of insulating material.

The third cavity corresponding to the contact electrode for contacting the second electrode of the capacitor may have an extension parallel to the surface of the substrate which extends beyond one edge of the second electrode of the capacitor on the opposite side of the second electrode from the extension of the first cavity corresponding to the first electrode. Such an extension of the third cavity corresponding to the contact electrode makes it possible for this contact electrode to be easily connected by means of a via placed through the second layer of insulating material, or through a fourth layer of insulating material formed on the third layer of insulating material.

To obtain a stack consisting of more than two electrodes, steps /el to /j/ may be repeated again, starting from the contact electrode for contacting the second electrode, which fulfils the function of the first electrode of the capacitor. In particular, a lithography mask that had been used during the first execution of step /f/ may be used again for the repetitions of this step, so as to obtain electrodes that are identical in the corresponding metallization layers.

### BRIEF DESCRIPTION OF THE DRAWINGS

Other characteristics and advantages of the invention will become further apparent on reading the description which follows. The latter is purely illustrative and should be read in conjunction with the appended drawings, in which:

FIGS. 1 to 6 illustrate various steps of a process for producing an integrated electronic circuit according to one particular embodiment of the invention; and

FIGS. 7 to 10 illustrate various steps of a process for producing an integrated electronic circuit according to an improvement of the invention.

### DETAILED DESCRIPTION OF THE DRAWINGS

In these figures, for the sake of clarity, the dimensions of the various parts of components shown have not been drawn to scale. These figures are sectional views of a substantially planar substrate on which a capacitor of MIM (Metal-Insulator-Metal) type has been produced. The sectional views are considered in a plane perpendicular to the surface of the substrate. The substrate is placed in the bottom part of each figure and N denotes a direction perpendicular to the surface of the substrate, directed upwards in the figures. L denotes that direction parallel to the surface of the substrate which lies in the plane of the figures. Hereafter, the terms “on,” “under,” “lower” and “upper” are used with reference to this orientation. Moreover, in all the figures, identical references correspond to identical elements.

In what follows, the individual process steps for fabricating an integrated electronic circuit that are known to those skilled in the art are not described in detail. A description will be limited to only a succession of individual steps that allows a circuit according to embodiments of the invention to be produced.

In FIG. 1, a substrate 1001, for example a silicon substrate, bears various electronic components, such as transistors 1002, on its upper surface, denoted by S. The transistors 1002 may be separated from one another by electrically isolating portions 1003, which may be of the STI (shallow trench isolation) type. An intermediate insulating layer 1010 is placed on the surface S, through which electrical connections 1004 connect the gates of the transistors 1002. The substrate 1000 and the layer 1010, with the components formed thereon, together constitute a lower part of the integrated electronic circuit, which is referenced overall by 1000. In general, the lower part 1000 of the circuit includes the active components thereof.

A first metallization layer is then produced on the intermediate layer 1010. To do this, an electrically insulating layer 101 is deposited on the layer 1010. In the damascene process, the layer 101 is essentially based on silica (SiO₂) and includes cavities formed by etching. The cavities C11 shown correspond for example to tracks, some of which may be placed above the connections 1004. It will be understood that the cavities C11 may be produced in any number in the layer 101 and may have any shape and be positioned freely so as to be parallel with the surface S away from the intended location of the capacitor, depending on the design of the circuit.

A cavity C1 is formed at the same time as the cavities C11, at the intended location of a first capacitor electrode. The dimensions of the cavity C1 may be between 1 μm (micron) and 100 μm, parallel to the surface S. The depth of the cavity C1, parallel to the direction N, is identical to that of the cavities C11 and corresponds to the thickness of the layer 101.

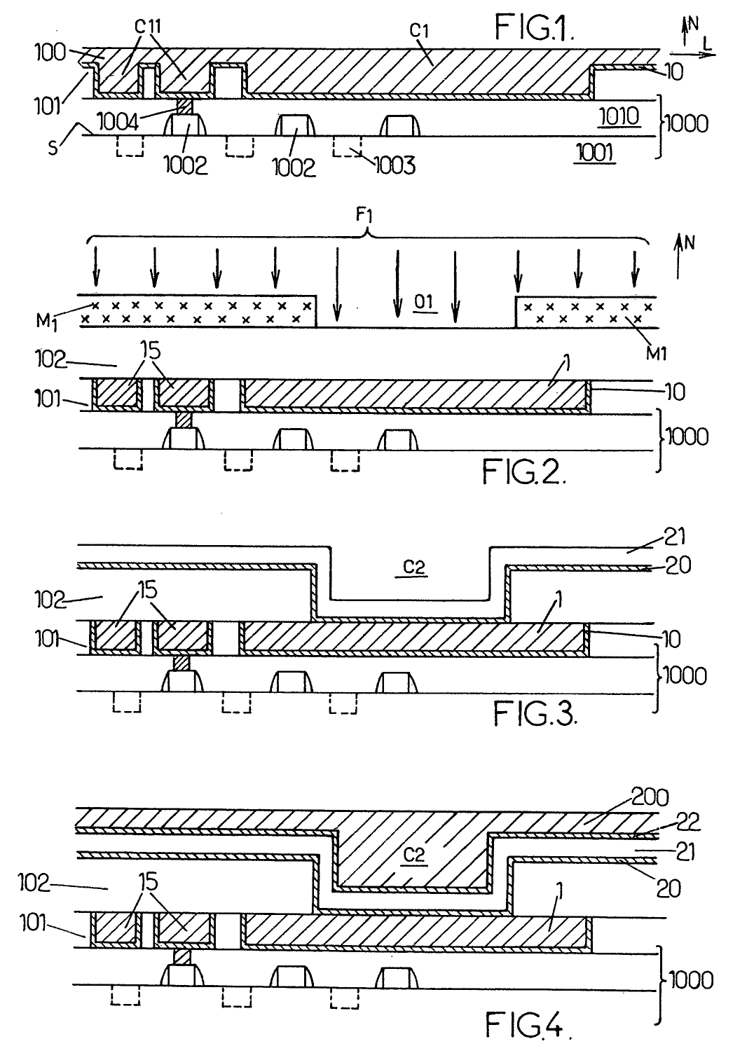

A layer 10 of titanium nitride (TiN), tantalum nitride (TaN), tungsten (W) or silicon nitride (Si₃N₄), for example, followed by a conducting layer 100, for example made of copper (Cu), are deposited in succession on the entire circuit. The thickness of the layer 10 may for example be less than 5 nm (nanometers) and the thickness of the layer 100 is sufficient to fill the cavities C1 and C11. The layer 10 forms a barrier preventing the diffusion of atoms from the layer 100 into the material of the layer 101. Finally, the circuit is polished on its upper surface in order to remove the materials of the layers 10 and 100 present between the cavities C11 and C1. This polishing may be carried out using the CMP (Chemical-Mechanical Polishing) process. A first level of connections of the circuit is thus obtained, which comprises a capacitor electrode 1 (FIG. 2), formed in the cavity C1 by a residual portion of the layer 100, and tracks 15 formed in the cavities C11. It should be mentioned that in the embodiment of the invention that is described here, formation of the electrode 1 does not require additional process steps nor an additional lithography mask, compared with the known process for producing an integrated electronic circuit metallization level. In the embodiment of the invention described here, the process for forming the first metallization level, which contains the electrode 1, is the damascene process.

A second layer 102 of insulating material is then formed on the circuit followed by a lithography resist mask M1. The layer 102 may be made of silica and have a thickness of approximately 50 nm in the direction N. An aperture O1 is produced in the mask M1 by lithography, and then the layer 102 is selectively etched, for example by directing a flux F1 of accelerated plasma particles onto the upper surface of the circuit, parallel to the direction N and in the opposite sense thereto. Such an etching process is known as anisotropic dry etching. The etching is continued until the material of the layer 102 is completely removed at the location of the aperture O1 and stopped when part of the electrode 1 is exposed. A cavity C2 (FIG. 3) is thus formed in the layer 102, passing right through the latter in the direction N.

Next, a layer 20 followed by a layer 21 are deposited on the circuit, under conditions suitable for obtaining conformal coatings—the layers 20 and 21 are continuous and in particular cover the bottom and the side walls of the cavity C2. The layer 20 may be identical to the layer 10, and the layer 21 is made of a dielectric that may have a high permittivity. As examples, the layer 21 may in particular be made of silicon nitride (Si₃N₄), hafnium oxide (HfO₂), tantalum oxide (Ta₂O₅), alumina (Al₂O₃) or strontium titanium oxide (SrTiO₃). The layer 21 may also consist of several superposed individual layers. The configuration of the circuit illustrated by FIG. 3 is therefore obtained.

Using the damascene process, a layer 22 and a layer 200 are then deposited in succession on the circuit (FIG. 4), which layers may be identical to the layers 20 and 100 respectively. The layer 20 conformally covers the circuit in its configuration illustrated by FIG. 3 and the layer 200 fills the cavity C2. The circuit is then polished on its upper surface, for example using the CMP process, until the materials of the layers 200, 22, 21 and then 20, between and around the cavity C2, are removed.

The configuration of the circuit illustrated by FIG. 5 is obtained. The cavity C2 then contains respective residual portions of the layers 20, 21, 22 and 200. The residual portion of layer 200 forms a second capacitor electrode, with the reference 2. It is located above the electrode 1 and is separated from the latter by the residual portions of the layers 20-22. The electrodes 1 and 2 thus form, with the residual portions of the layers 20-22, a capacitor denoted by Γ1.

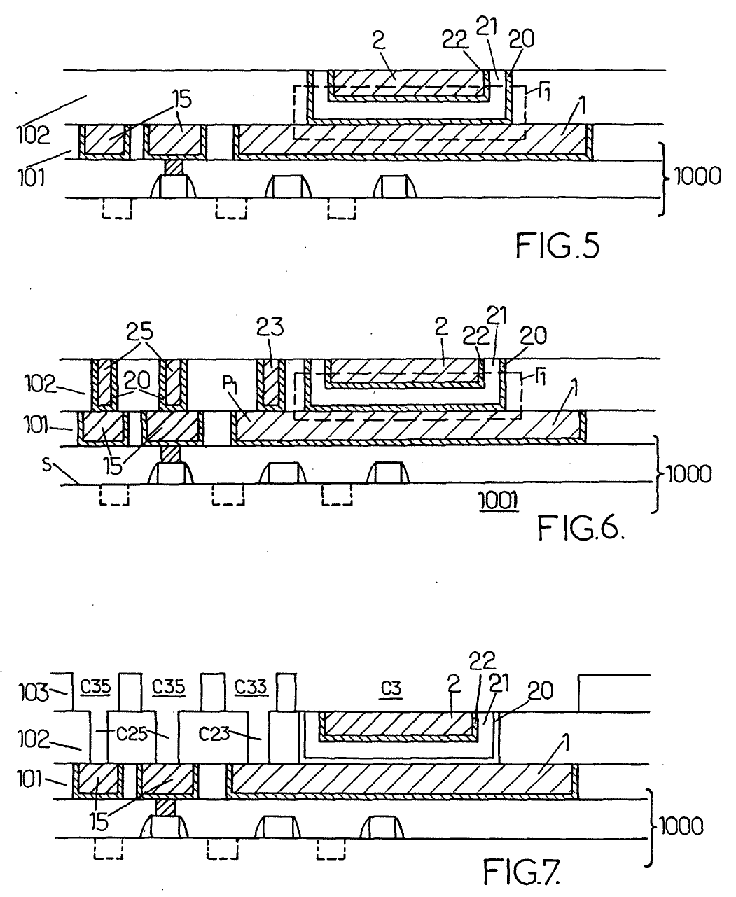

Vias 23 and 25 (FIG. 6) are then formed in the layer 102, there being any number of these vias depending on the design of the circuit. These vias, the dielectric portion 21 and the electrode 2 form part of a second connection level of the circuit, which is located above the first connection level. This second connection level has been produced by adapting the damascene process as known to those skilled in the art. This adaptation requires only a single additional lithography mask for defining the dimensions of the electrode 2.

The vias 23 and 25 may produce electrical connections that connect certain of the tracks 15 of the first level of connections. Furthermore, as shown in FIG. 6, the electrode 1 possesses an extension P1 that extends beyond one side of the electrode 2, parallel to the surface S. The via 23, which is in electrical contact with the electrode 1 on the extension P1, may constitute a connection terminal for the electrode 1.

In this particular embodiment of the invention, the residual portions of the layer 20 in the cavities C23 and C25 provide electrical contacts between the vias 25 and the tracks 15 on the one hand, and between the via 23 and the electrode 1 on the other. To this end, the material of the layer 20 is electrically conducting.

The residual portions of the layers 20 and 22 in the cavity C2 form barriers that prevent the diffusion of copper atoms from the electrodes 1 and 2 into the dielectric portion 21. In this way, the portion 21 remains essentially free of impurities, which contributes to a high breakdown voltage of the capacitor Γ1 being obtained. To do this, the materials of the layers 20 and 22 are impermeable to atoms from the layers 100 and 200.

Moreover, the layers 20 and 22 are preferably made of the same material, so that the electrical behavior of the capacitor Γ1 is identical whatever its polarity. Titanium nitride, tantalum nitride and tungsten are therefore particularly suitable materials for the layers 20 and 22.

When the dielectric of the portion 21 is silicon nitride, the barrier layer 20 is not essential and may be omitted. In this case, the portion 21 fulfils both the atom diffusion barrier function and the dielectric function of the capacitor.

The production of the integrated electronic circuit may then be continued in a usual manner known to those skilled in the art, by forming upper levels of connections placed above the second level of connections.

An improvement of the invention will now be described, which allows several capacitors superposed perpendicular to the surface of the substrate to be produced while still maintaining a high level of integration.

An integrated electronic circuit being produced is assumed to correspond to the configuration illustrated in FIG. 5, the layer 20 being omitted or being made of an electrically insulating material. For this reason, the layer 20 is not shown hatched in FIGS. 7 to 10.

A third layer of electrically insulating material, with the reference 103 in FIG. 7, is formed on top of the layer 102. The layer 103 may have a thickness, in the direction N, identical to that of the layer 101. Cavities C3, C33, C35, C23 and C25 are then formed in the following manner:

the cavities C3, C33 and C35 are located in the layer 103 only, passing through the latter over its entire thickness;

the cavities C3 and C33 lie, non-contiguously, above the electrode 1

the cavities C33 and C35 have dimensions, parallel to the surface S, which correspond to tracks;

the cavity C3 has dimensions, parallel to the surface S, which correspond to a capacitor electrode;

the cavities C23 and C25 are located in the layer 102, passing through the latter over its entire thickness;

the cavities C23 and C25 have dimensions, parallel to the surface S, which correspond to vias; and

certain of the cavities C33 and C35 may be located above cavities C23 and C25 along the direction N.

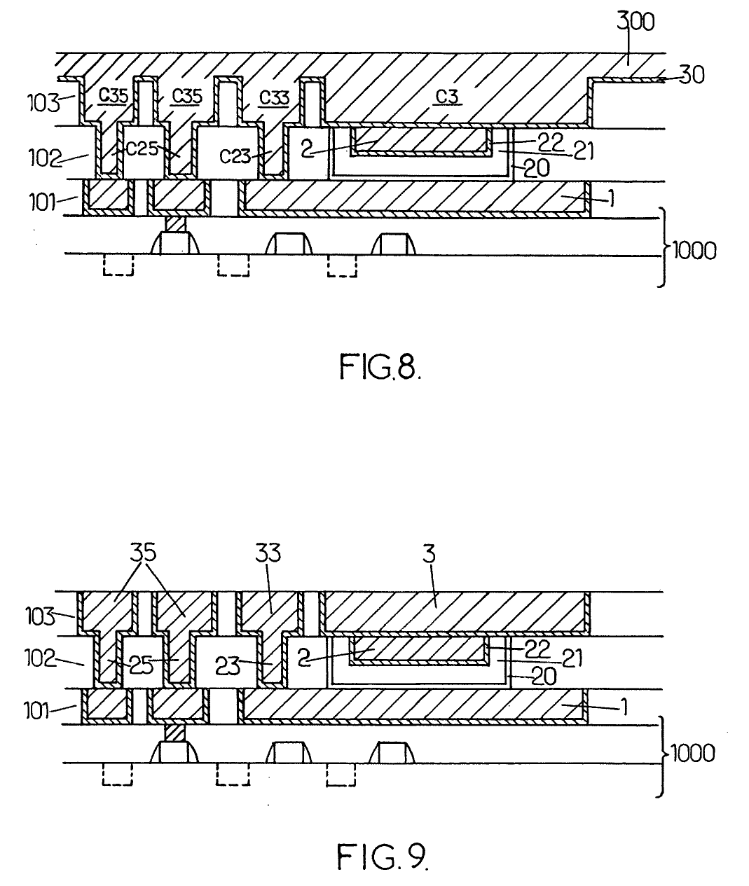

Next, in accordance with FIG. 8, a barrier layer 30 and then a layer 300 of conducting material are deposited in succession on the circuit. The materials of the layers 30 and 300 may be identical to those of the layers 10 and 100 respectively. The layer 30 has a thickness of 5 nm for example and is deposited under conditions suitable for obtaining a conformal coating. The layer 300 has a sufficient thickness for filling the cavities C23, C25, C3, C33 and C35 up to the level of the upper surface of the layer 103.

The circuit is then polished on its upper surface so as to obtain a planar surface and to remove the conducting material of the layer 300 between the cavities C3, C33 and C35.

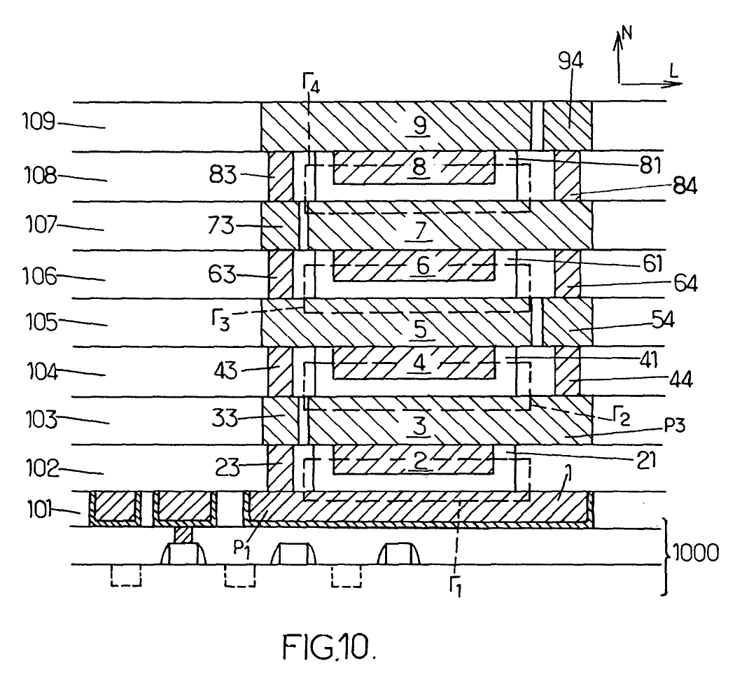

The configuration of the circuit illustrated by FIG. 9 is therefore obtained. The second layer of connections of the circuit now corresponds to the union of the layers 102 and 103 and possesses the structure of a dual-damascene layer. The layer 102 contains vias 23 and 25, formed in the cavities C23 and C25 respectively, and the layer 103 contains tracks 33 and 35, formed in the cavities C33 and C35 respectively. The vias 23, 25 and the tracks 33 and 35 have been produced using the dual-damascene process. The layer 103 also contains a contact electrode 3 of conducting material formed in the cavity C3. The electrode 2 lies in the same layer level as the vias 23 and 25, and the contact electrode 3 lies in the same layer level as the tracks 33 and 35. The contact electrode 3 may be defined by the same lithography mask as for the tracks 33 and 35, so that it incurs no significant additional cost for the circuit.

A third metallization layer may be produced on the layer 103 in the same way as the second metallization layer on the layer 101. This third metallization layer, again of the dual-damascene type, comprises individual layers 104 and 105 of insulating material (FIG. 10). Vias 43, 44 and an electrode 4 placed above the contact electrode 3 are formed in the layer 104. The electrode 4 is separated from the contact electrode 3 by a portion 41 of dielectric, which may itself be sandwiched between two portions of barrier layers preventing the diffusion of atoms from the contact electrode 3 and/or from the electrode 4. These barrier layers may be made of an electrically insulating material and of an electrically conducting material for the layer lying below and the layer lying above, respectively, the dielectric portion 41. Optionally, the barrier layer lying below the dielectric portion 41 may be omitted.

In particular, the lithography mask that was used to define the electrode 2 may be reused for defining the electrode 4, thereby reducing the manufacturing cost of the circuit. However, the layers 104 and 105 may include connections, i.e. tracks and/or vias, of any number and any shape. These connections of the layers 104 and 105 may be located above the substrate at various points, and especially at different points from those of the connections of the layers 102 and 103, using lithography masks dedicated to each layer.

In the circuit thus obtained, the contact electrode 3 has two different electrical functions. Firstly, it constitutes an electrical connection which connects the electrode 2, given that it is in contact with the latter via its lower face. This contact, which is formed over the entire upper surface of the electrode 2, has a very low electrical resistance. Secondly, the contact electrode 3 forms, by its upper surface, with the electrode 4 and the dielectric portion 41, a second capacitor. This second capacitor is denoted by F2 in FIG. 10. The contact electrode 3 therefore also constitutes the lower electrode of the capacitor F2.

The via 43 and the track 33 may be superposed on top of the via 23 in order to extend the electrical connection of the electrode 1 through the layers 103 and 104. Moreover, the contact electrode 3 may advantageously have an extension P3 that extends laterally beyond one edge of the electrode 2. The extension P3 is located on one side of the electrode 2, different from that of the extension P1 of the cavity C1. The via 44 may then form an electrical connection that connects the contact electrode 3 to the extension P3 through the layer 104. In FIG. 10, the extensions P1 and P3 are located on two opposed sides of the capacitors Γ1 and Γ2 along the direction L, but any other arrangement of these extensions may be adopted, in which the extensions P1 and P3 are not superposed in the direction N.

The layer 105 contains a track 54 and an contact electrode 5, which have been formed in the same way as the track 33 and the contact electrode 3. Optionally, the contact electrode 5, which is in contact with the electrode 4, may have an extension similar to the extension PI of the electrode 1, which will then come into contact with the via 43. The electrode contact 5 may thus be electrically connected to the electrode 1.

FIG. 10 illustrates an integrated electronic circuit, in which the process for producing the layers 104 and 105 that has just been described was repeated two further times. The layer 106 comprises the electrode 6, the dielectric portion 61 and the vias 63, 64. Likewise, the layer 108 comprises the electrode 8, the dielectric portion 81 and the vias 83, 84. Optionally, the electrodes 6 and 8 may be produced by using again the lithography mask used to define the dimensions of the cavity C2 corresponding to the electrode 2. The layers 107 and 109 comprise contact electrodes 7, 9 and vias 73, 94. Owing to the superposition of the contact electrodes 3, 5, 7, 9 and of the electrodes 1, 2, 4, 6, 8, a capacitor F3 is obtained that comprises an upper part of the contact electrode 5, the dielectric portion 61 and the electrode 6. A capacitor Γ4 is also obtained, which comprises an upper part of the electrode 7, the dielectric portion 81 and the electrode 8. For the sake of clarity of FIG. 10, the portions of barrier layers preventing any atomic diffusion have not been shown in the layers 102 to 109. Likewise, connections may be formed in the layers 102-109 other than those shown in FIG. 10, outside that part of the circuit occupied by the capacitors Γ1-Γ4.

The capacitors Γ1 -Γ4 thus produced may be electrically combined in various ways, depending on the arrangement of the vias and of the tracks in each level of connections. The capacitive system comprising the capacitors Γ1-Γ4 may then have variable capacitance values, while still maintaining identical dimensions for those parts of the connection levels that are occupied by the system. These dimensions are small, thanks to the superposition of the various elements of the capacitive system within the integrated electronic circuit and thanks to the dual electrical function of the contact electrodes 3, 5 and 7. When the vias of the third, fifth, seventh and ninth levels, with the references 33, 54, 73 and 94 respectively, are located alternately plumb with the extensions P1 and P3, as shown in FIG. 10, a hybrid series/parallel combination of the capacitors Γ1-Γ4 is obtained.

Of course, many modifications may be introduced into the integrated electronic circuits that have been described in detail above, while still maintaining at least certain of the advantages of the invention. In particular, certain of the portions of atomic diffusion barrier layers may have compositions differing from those that were indicated by way of examples. Likewise, the number of metallization layers in which capacitor elements according to the invention are formed may also be changed or increased, for example so as to obtain higher capacitances.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. An integrated electronic circuit, comprising:
a substrate;
electrical connections located in metallization layers superposed on top of a surface of said substrate;
a stack of 2n superposed electrodes parallel to the surface of the substrate, counted starting from the electrode closest to the substrate, n being an integer strictly greater than 1, the electrodes 2i and 2i−1 forming together a capacitor for each integer i from 1 to n, and being placed in adjacent metallization layers, each of those metallization layers containing some of said electrical connections; in which:
the electrodes 2j and 2j+1 are electrically connected together, for each strictly positive integer j less than n;
the electrodes 1 and 4k+1 are electrically connected together to form a first input of a capacitive system comprising the 2n electrodes, for any strictly positive integer k less than or equal to n/2; and
the electrodes 3 and 4l+3 are electrically connected together to form a second input of the capacitive system, for any strictly positive integer 1 less than n/2.

2. The circuit according to claim 1, wherein one of the two electrodes 2i and 2i−1 of each capacitor has an extension extending beyond one side of the other electrode of the capacitor, parallel to the surface of the substrate.

3. The circuit according to claim 1, wherein the adjacent metallization layers are damascene or dual-damascene layers, and wherein the two electrodes 2i and 2i−1 of each capacitor are based on copper and are located in respective cavities of the corresponding metallization layers.

4. The circuit according to claim 3, wherein the electrode 2i−1 closest to the substrate for each capacitor is located in a damascene layer.

5. The circuit according to claim 3, wherein the electrode 2i furthest from the substrate for each capacitor is located in a via level of a dual-damascene layer.

6. The circuit according to claim 1, wherein each capacitor comprises, in order starting from that side of the capacitor which is closest to the substrate: the electrode 2i−1, a dielectric layer, a layer forming an atom diffusion barrier, and the electrode 2i.

7. The circuit according to claim 6, wherein the barrier layer is made of an electrically conducting material.

8. The circuit according to claim 6, wherein each capacitor further comprises another layer forming an atom diffusion barrier located between the electrode 2i−1 and the dielectric layer of that capacitor, and wherein the respective materials of the two barrier layers are identical.

9. The circuit according to claim 1, wherein the electrodes 2j and 2j+1 are placed in adjacent metallization layers and are in electrical contact with each other, for each strictly positive integer j less than n, over a contact area substantially equal to the area of the electrode 2j parallel to the surface of the substrate.

10. The circuit according to claim 1, wherein the electrodes 2i and 2i′ are identical, i and i′ being two strictly positive integers less than or equal to n.

11. A process for producing an electronic circuit incorporating several capacitors, the process comprising:
/a/ forming a first layer of electrically insulating material on top of and parallel to a surface of a substrate of the circuit;
/b/ etching, in the first layer of insulating material, first cavities corresponding to first electrical connections and to at least a first electrode of a first one of the capacitors, respectively;
/c/ filling the first cavities with a first electrically conducting material so as to form the first connections and the first electrode;
/d/ removing the first conducting material between the first connections and around the first electrode above the first layer of insulating material;
/e/ forming a second layer of electrically insulating material on the first layer;
/f/ etching, in the second layer of insulating material, at least a second cavity corresponding to a second electrode of the first capacitor, lying above the first electrode;
/g/ forming a layer of a dielectric covering the bottom and the walls of the second cavity corresponding to the second electrode;
/h/ etching second cavities corresponding to second electrical connections in the second layer of insulating material;
/i/ filling the second cavities with at least a second electrically conducting material so as to form the second connections and the second electrode; and
/j/ removing the second conducting material between the second connections and/or around the second electrode above the second layer of insulating material,
wherein the first cavity corresponding to the first electrode of the first capacitor has an extension that extends beyond one edge of the second electrode of said first capacitor parallel to the surface of the substrate, and wherein one of the second cavities corresponding to a second connection is etched in step /h/ in the second layer of insulating material in order to form an electrical connection that connects said first electrode to said extension;
the process further comprising the following steps:
/k/ forming a third layer of electrically insulating material on the second layer of insulating material;
/l/ etching, in the third layer of insulating material, third cavities corresponding to third electrical connections and to at least one contact electrode for electrically contacting the second electrode of the first capacitor, respectively, the third cavity that corresponds to the contact electrode being located above the second electrode and extending through the third layer of insulating material between two opposed sides of said third layer, along the direction perpendicular to the surface of the substrate; and
/m/ filling the third cavities with a third electrically conducting material so as to form the third connections and the contact electrode for contacting the second electrode,
wherein one of the third cavities corresponding to a third connection is etched at step /l/ through the third layer of insulating material in order to form an electrical connection that extends the connection connecting the first electrode of the first capacitor through the second layer of insulating material,
and wherein steps /e/ to /j/ are repeated, starting from the contact electrode for contacting the second electrode, fulfilling the function of the first capacitor electrode, so as to form as many supplementary capacitors.

12. The process according to claim 11, wherein steps /d/ and/or /j/ each comprise at least one chemical-mechanical polishing operation.

13. The process according to claim 11, wherein the second cavity corresponding to the second capacitor electrode, etched in step /f/, extends through the second layer of insulating material between two opposed sides of said second layer, in a direction perpendicular to the surface of the substrate.

14. The process according to claim 11, wherein certain of the first electrical connections formed at the same time as the first capacitor electrode in step /c/ comprise tracks.

15. The process according to claim 11, further comprising:
between steps /f/ and /g/, producing a first layer of a material forming an atom diffusion barrier, said layer covering the bottom and walls of the second cavity corresponding to the second electrode; and
between steps /g/ and /i/, producing a second layer of a material forming an atom diffusion barrier, said layer covering the bottom and the walls of the second cavity that corresponds to the second electrode and that is already provided with the layer of dielectric.

16. The process according to claim 15, wherein the respective materials of the first and second barrier layers are identical.

17. The process according to claim 15, wherein the respective materials of the first and second barrier layers are electrically conducting.

18. The process according to claim 11, wherein step /h/ is carried out at the same time as step /l/, after step /k/, and wherein step /i/ is carried out at the same time as step /m/.

19. The process according to claim 18, wherein the second and third connections are vias and tracks of a dual-damascene metallization layer, respectively.

20. The process according to claim 11, wherein the third cavity corresponding to the contact electrode for contacting the second capacitor electrode has an extension parallel to the surface of the substrate and extending beyond one edge of the second capacitor electrode on the opposite side of said second electrode from the extension of the first cavity corresponding to the first electrode.

21. The process according to claim 11, wherein a lithography mask used during the first execution of step /f/ is used again for at least certain of the repetitions of this step, so as to obtain identical electrodes in the corresponding metallization layers.
